(19) United States
(12) Patent Application Publication
(10) Pub. No.: US 2007/0141850 A1
(43) Pub. Date: Jun. 21, 2007

(54) Wet Treatment of Hafnium Containing Materials

(76) Inventors: Audrey Dupont, Dresden (DE); Kristin Schupke, Dresden (DE); Stefan Jakschik, Dresden (DE); Alejandro Avellan, Dresden (DE)

Correspondence Address: SLATER & MATSIL LLP, 17950 PRESTON ROAD, SUITE 1000, DALLAS, TX, 75252, US

(21) Appl. No.: 11/565,227

(22) Filed: Nov. 30, 2006

Related U.S. Application Data
(62) Division of application No. 11/184,060, filed on Jul. 18, 2005, now abandoned.

(51) Int. Cl. C03C 15/00; H01L 21/302; B44C 1/22

(52) U.S. Cl. 438/745; 216/96

(57) ABSTRACT

A semiconductor product includes an exposed Hafnium-containing layer. The Hafnium-containing layer is treated with a solution that includes a low ionic strength organic substance.

This is a divisional application of U.S. application Ser. No. 11/184,060, which was filed on Jul. 18, 2005 and is incorporated herein by reference.

### TECHNICAL FIELD

This invention relates generally to a solution to be used in the wet treatment of Hafnium containing materials, a use of said solution and a process using said solution.

### BACKGROUND

In the processing or production of semiconductor devices, in particular DRAM, the feature size decreases continuously. For certain components, like e.g., deep trench capacitors, new materials with improved physical and chemical properties are required in order to compensate for manufacturing problems encountered while using the known materials.

Therefore, different materials are employed as substrates (doped Si, metals, etc.), dielectrics (e.g., nitrides, Hafnium compounds, other high-k materials), nodes (nitrides, Al₂O₃) and electrodes (TiN, TaN, Ru, etc.)

Dielectric layers, in particular high-k layers are becoming more and more important. High-k materials are materials with dielectric constant greater than 3.9 (dielectric constant of SiO₂).

In this field, Hafnium—containing materials like HfO₂ and its combinations with aluminum or silicon are promising candidates to replace silicon dioxide (SiO₂) in gate structures. See e.g., Paraschiv et al, “HF Based Solutions for HfO₂ Removal; Effect of pH and Temperature on HfO₂:SiO₂ Etch Selectivity, Conf. paper 7^{th} International Symposium on Ultra Clean Processing of Silicon Surfaces, UCPSS 2004 Sep. 19-22; Brussels Belgium, which is incorporated herein by reference.

In particular, HfSiOₓ and HfAlOₓ have dielectric constants between 10 and 20. Therefore, for equivalent capacity, high-k films are thicker than those of SiO₂, which confer them lower leakage and lower power dissipation.

For use of high-k materials in production, the important factors to take into account are electrical properties (dielectric constants, band gap and band alignment), thermal stability, deposition method and etching ability (practical etch rate).

The structuring of Hafnium containing materials is achieved with wet chemistries, primarily based on hydrofluoric acid (HF). This is described e.g., in the report International Sematech, “Etching of High-k Dielectrics with Wet Chemistries,” Jul. 31, 2002, which is incorporated herein by reference.

Especially the wet etching of Hafnium containing material poses a problem since Hafnium is very inert. Conventional etch chemistries are very slow in etching Hafnium containing materials. Table 1 shows etch of various Hafnium containing materials in different wet chemistry (etch rates are smaller than 1 nm/min apart from HFEG). So far best results for the etching of Hafnium containing materials were obtained by using fuming sulphuric acid at 150° C. or using hydrofluoric acid (HF) based chemistries. This solution is however not applicable in a semiconductor industry environment.

Furthermore, the problem of selective etching arises in this context. The problem in this context is that HF based chemistries are not selective to species like SiO₂, LP Si₃N₄ (being a furnace nitride deposited at ˜780° C.) and Al₂O₃.

### SUMMARY OF THE INVENTION

Selective and efficient wet treatment in the production of semiconductor devices can be achieved with a solution for the wet treatment of high-k material containing Hafnium when the solution comprises a low ionic strength organic substance.

The surprising effect of low ionic strength organic substances in this context is the changing of the ionic strength of the solution. In organic solvents, the ionic strength controls the balance of the HF active etching species such as HF and H₂F₂. This change results in high etch rates and good selectivities for Hafnium containing materials.

The use of the solution and a process for the wet etching applying the solution are also part of the invention.

Other objects and advantages of the invention become apparent upon reading of the detailed description of the invention, and the appended claims provided below, and upon reference to the drawings and tables.

### BRIEF DESCRIPTION OF TABLES AND DRAWINGS

For a more complete understanding of the present invention, and the advantages thereof, reference is now made to the following descriptions taken in conjunction with the accompanying drawing, in which:

Table 1: Etch rate of Hafnium containing materials using different wet chemistries.

Table 2: Etch rate and selectivity data from various materials against Hafnium containing materials using HFEG.

FIG. 1: Flowchart of an embodiment of the process according to the present invention.

FIG. 2: Schematic drawing of a DRAM cell using a Hafnium containing material as dielectric.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In table 1 a number of experiments are described. In experiments 1 to 7 a HfO₂ substrate was subjected to different known wet chemistries. The details of the substances are given in column 4 using the following abbreviations:

SC1: Water (50 volume-%, 2 volume-% hydrogen peroxide, 1 volume-% ammonia);

DHF: 200 part water, 1 part of 49 weight-% HF;

BHF: 88 volume-% water, 10 volume-% ammonia fluoride, 2 volume-% of 49 weight-% HF;

Hot Phos: phosphoric acid 86 weight-%;

The abbreviation TR stands for total removal of the Hafnium containing layer; and

SOPM: Sulphuric acid (84 volume-%), ozone (O₃ concentration>100 g/m3) and hydrogen peroxide (1 volume-%).

Experiments 8 to 12 were conducted with substrates made of HfSiOₓ (with 20% HfO₂) using again, known wet chemistries. In addition to the above mentioned chemistries the following was used:

SC2: 20 parts (volume) water, 1 part hydrogen peroxide (volume), 1 part HCl (volume); and

BSG: 14 parts H₂SO₄ (volume), 1 part hydrofluoric acid (volume).

As can be seen from the etch rate data, the etch rates are very low.

Experiments 14 and 15 where conducted with an embodiment of the solution according to the present invention.

HFEG, as used here, is a hydrofluoric acid spiked with 4 volume-% ethylene glycol (OH—H₂C—CH₂—OH). The ethylene glycol is a low ionic strength organic substance.

As can be seen from Table 1, the etch rates of the embodiments of the present invention are much higher than with all other chemistries.

In principle, a glycol can be used as the low ionic strength organic substance, the non-limiting examples given above used a particular glycol. Other low ionic strength organic substances are polyglycol or acetate glycol.

Furthermore, the composition of the solution for the wet etching according to the invention can vary. Principally, more than 50 weight-% glycol (like e.g., ethylene glycol) and less than 50 weight-% hydrofluoric acid can be used. More particularly, more than 90 weight-% glycol (like e.g., ethylene glycol) and less than 10 weight-% hydrofluoric acid can be used. More particularly, more than 90 to less than 98 weight-% glycol (e.g., ethylene glycol) and more than 2 to less than 10 weight-% hydrofluoric acid can be used.

Table 2 shows experimental results comparing different experiments using only HFEG (HF spiked with 4 volume-% ethylene glycol).

In experiments 1 to 3, Hafnium containing materials were etched with HFEG solution as mentioned above. Experiments 4 to 7 were control experiments, in which different materials where treated with the same HFEG solution. The etch rate of the Hafnium containing material against the other materials was then calculated and is given in column 5.

As can be seen from Table 2, the usage of a mixture of hydrofluoric acid and ethylene glycol (HFEG) achieves very high selectivities. In the experiments, a mixture of 96 weight-% ethylene glycol with 4 weight-% hydrofluoric acid was used. The anneal conditions were 900° C., using NH₃ for the Hafnium silicates and 1000° C., using N₂ for the aluminum oxide and TiN.

The very high etch rate for HfSiOₓ using HFEG shows that this chemistry is very effective (see experiments 1 to 3). In HfSiOₓ, the Hafnium content varies between 50 and 90%, 80% being a common value.

When compared against other materials (see experiments 4 to 7) the high selectivity in etching Hafnium silicates against other materials is indicated.

The experiments show that Hafnium containing materials, especially Hafnium silicates can be used as dielectric materials in deep trenches of DRAMs. In this type of applications, the dielectric must be recessed selectively to other materials, i.e., the pad nitride in the substrate, the electrode (TiN) for MIM application and the aluminum oxide as node.

The use of HFEG as described above, results in a wet etch chemistry with a low water content and a ionic strength close to zero. This favors the active etching species such as HF and H₂F₂ coming from the hydrofluoric acid.

The solution, the use and the process according to the invention, allows the wet etching of Hafnium containing materials, especially for semiconductor manufacturing processes for nodes smaller than 60 nm.

Furthermore, it was found that there is no Hafnium cross contamination on the wafers so that the HFEG bath can be used for other processes, such as oxide etch.

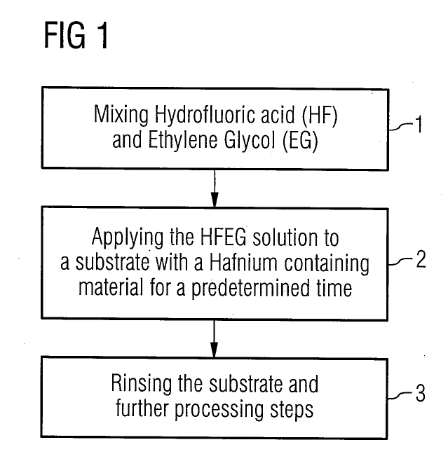

An embodiment of the process according to the invention is depicted in FIG. 1. In process step 1, the solution of hydrofluoric acid and ethylene glycol is prepared. As mentioned above, the mixture is 96 weight-% ethylene glycol and 4 weight-% hydrofluoric acid, i.e., the ethylene glycol is spiked with hydrofluoric acid. In one embodiment, the solution is prepared in-line, i.e., at the etching tool.

In the following process step 2, the solution is applied to the substrate for a predetermined time. The Hafnium containing material was deposited on a blanket substrate using ALCVD (atomic layer chemical vapor deposition).

At last the substrate is rinsed and dried in process step 3 and further process steps follow.

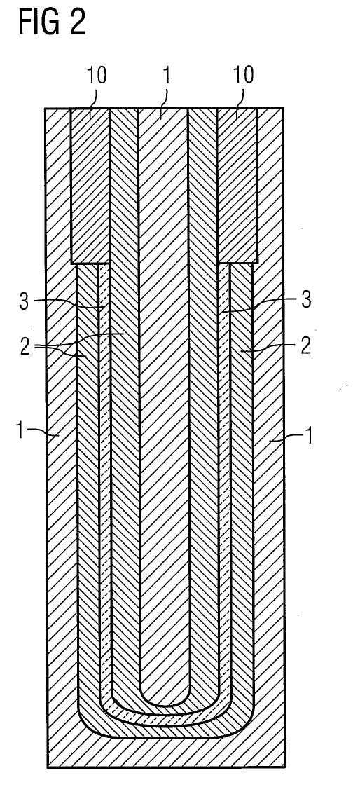

In FIG. 2, a typical application of an embodiment of the present invention is described. Here a Hafnium containing material is used in a buried collar 10 of a deep trench in a DRAM cell (ground rule 50 nm). The DRAM cell is only shown schematically.

Apart from the wet etching (treatment) of the Hafnium containing material using HFEG solution, the process steps are known in principle.

The deep trench is first etched into a silicon substrate 1. Then metal 2 is deposited in the deep trench. The metal 2 in the deep trench is then etched away, the surface of the metal is then lined with a dielectric layer 3. Following that, the buried collar 10 made of Hafnium containing material (HfSiOₓ or HfAlOₓ) is recessed selectively to the other materials. After the etching step using an embodiment of the invention (HFEG, ethylene glycol spiking with 4% HF), the trench is filled with metal 4 and, after another etching step, with silicon 5.

While FIG. 2 illustrates a trench capacitor, it is understood that the teachings equally apply to stack capacitors.

In addition, other structures could utilize the teachings of the present invention. For example, a transistor that includes a Hafnium containing gate dielectric and be formed using the solution as described herein. Further, non-volatile memories could include materials that are etched using teachings of the present invention.

TABLE 1

| | | Thermal | | Process | Etch Rate/ |
|---|---|---|---|---|---|
| No. | Substrate | Treatment | Chemistry | Time | (nm/min) |
| 1 | HfO₂ | — | SC1 (50:1:2), 65° C. | 3 min | 0 |
| 2 | HfO₂ | — | DHF (200:1), 23° C. | 1 min | 0.164 |
| 3 | HfO₂ | — | BHF (88:10:2), 23° C. | 30 s | 2.64 |
| 4 | HfO₂ | — | Hot Phos 86%, | 60 s | TR |
| | | | 158° C. | | |
| 5 | HfO₂ | — | SOPM, 100° C. | 1 min 32 s | 0.360 |
| 6 | HfO₂ | — | SC1 (50:1:2), 65° C. | 3 min | 0 |
| 7 | HfO₂ | Anneal | Hot Phos 86%, | 3 min 30 s | 0 |
| | | | 158° C. | | |
| 8 | HfSiOx mix (80% | Anneal | SC1 (50:2:1), 65° C. | 5 min | 0.012 |
| | HfO₂) | | | | |
| 9 | HfSiOx mix (80% | Anneal | SC2 (20:1:1), 65° C. | 5 min | 0.040 |
| | HfO₂) | | | | |
| 10 | HfSiOx mix (80% | Anneal | DHF (250:1), 28° C. | 3 min 25 s | 0.010 |
| | HfO₂) | | | | |
| 11 | HfSiOx mix (80% | Anneal | Hot Phos 86%, | 3 points | 0.240 |
| | HfO₂) | | 160° C. | | |
| 12 | HfSiOx mix (80% | Anneal | H₂SO₄, 100° C. | 10 min | 0.015 |
| | HfO₂) | | | | |
| 13 | HfSiOx mix (80% | Anneal | H₂SO₄/HF (BSG) | 2 min 32 s | 0.240 |
| | HfO₂) | | 14:1, 60° C. | | |
| 14 | HfSiOx mix (80% | Anneal | HFEG (4%), 65° C. | 1 min 49 s | >>13 |
| | HfO₂) | | | | |
| 15 | HfSiOx mix (60% | Anneal | HFEG (4%), 65° C. | 1 min 49 s | >>13 |
| | HfO₂) | | | | |

TABLE 2

| | | | | Selectivity |
|---|---|---|---|---|
| | | Thermal | Etch Rate/ | (HfSiOₓ:said |
| No. | Substrate | Treatment | (nm/min) | material) |
| 1 | HfO₂ | Anneal | 0.13 | — |
| 2 | HfSiOx, (80% | Anneal | >>13 | — |
| | HfO2) | | | |
| 3 | HfSiOx, (60% | Anneal | >>13 | — |
| | HfO2) | | | |
| 4 | ALD TiN | Anneal | 0.03 | >>400:1 |
| 5 | ALD Al₂O₃ | Anneal | 0.14 | >>100:1 |
| 6 | LPCVD nitride | — | 1 | >>13:1 |
| 7 | Thermal Oxide | Anneal | 1 | >>13:1 |

What is claimed is:

1. A method of making a semiconductor device, the method comprising:
providing a semiconductor product that includes an exposed Hafnium-containing layer; and
treating the Hafnium-containing layer with a solution, the solution comprising a low ionic strength organic substance.

2. The method of claim 1, wherein the semiconductor product further includes a second exposed material and wherein treating the Hafnium-containing layer comprises etching the Hafnium-containing layer selectively with respect to the second exposed material, the second exposed material comprising Si₃N₄, Al₂O₃, TiN or SiO₂.

3. The method of claim 1, wherein the Hafnium-containing layer comprises a material comprising one of the group of HfO₂, HfO₂/Al₂O₃, HfO₂/SiO₂, HfSiOₓ, or HfAlOₓ, the Hafnium content in the Hafnium-containing layer varying between 50 and 90%.

4. The method of claim 1, further comprising annealing the Hafnium-containing layer prior to treating the Hafnium-containing layer.

5. The method of claim 4, wherein the Hafnium-containing layer comprises a material comprising one of the group of HfO₂, HfO₂/Al₂O₃, HfO₂/SiO₂, HfSiOₓ, or HfAlOₓ.

6. The method of claim 1, wherein treating the Hafnium-containing layer comprises wet etching the Hafnium-containing layer.

7. The method of claim 6, wherein the solution is applied to the Hafnium-containing layer for a time period, wherein the time period for the wet treatment is determined during the process in dependence of a process parameter.

8. The method of claim 6, wherein the solution is mixed immediately before treating the Hafnium-containing layer.

9. The method of claim 6, wherein the wet etching of the Hafnium-containing layer takes place at temperatures between 30 and 70° C.

10. The method of claim 1, wherein providing a semiconductor product that includes an exposed Hafnium-containing layer comprises depositing the Hafnium-containing layer using a method selected from the group consisting of ALD CVD, MOCVD, and PVD.

11. The method of claim 1, wherein the low ionic strength organic substance comprises at least a glycol.

12. The method of claim 11, wherein the glycol comprises at least one substance selected from the group consisting of ethylene glycol, polyglycol, and acetat glycol.

13. The method of claim 1, wherein the solution further comprises hydrofluoric acid.

14. The method of claim 1, wherein the solution includes more than 50 weight-% of at least one glycol and less than 50 weight-% hydrofluoric acid.

15. The method of claim 14, wherein the solution includes more than 90 weight-% of at least one glycol and less than 10 weight-% hydrofluoric acid.

16. The method of claim 15, wherein the solution includes more than 90 to less than 98 weight-% of at least one glycol and more than 2 to less than 10 weight-% hydrofluoric acid.

17. The method of claim 16, wherein the at least one glycol is selected from the group consisting of ethylene glycol polyglycol and acetate glycol.

18. The method of claim 17, consisting of 96 weight-% of at least one glycol and 4 weight-% hydrofluoric acid.

19. A method of making a capacitor, the method comprising:
forming a first conductor;
forming a dielectric layer adjacent the first conductor, the dielectric layer comprising a Hafnium-containing material;
wet etching the dielectric layer with a solution, the solution comprising a low ionic strength organic substance; and
forming a second conductor such that the dielectric layer is disposed between the first conductor and the second conductor.

20. The method of claim 19, wherein the low ionic strength organic substance comprises at least a glycol.
